(19) United States
(12) Patent Application Publication
(10) Pub. No.: US 2026/0123428 A1
(43) Pub. Date: Apr. 30, 2026

(54) Semiconductor Device and Method of Forming Power IC as PMIC with Magnetic Core

(71) Applicant: STATS ChipPAC Management Pte. Ltd., Singapore (SG)

(72) Inventors: Supin Lee, Incheon (KR); JiNa Song, Gyeonggi-do (KR); YoungIn Choi, Chungcheongbuk-do (KR); JeongHyun Yeo, Incheon (KR)

(73) Assignee: STATS ChipPAC Management Pte. Ltd., Singapore (SG)

(21) Appl. No.: 18/931,485

(22) Filed: Oct. 30, 2024

(51) Int. Cl. H01L 23/58; H01F 27/28; H01L 23/13; H01L 23/552; H01L 25/16

(52) U.S. Cl. CPC H10W 42/00; H01F 27/2804; H10D 1/20; H10W 42/20; H10W 70/68; H10W 90/00

(57) ABSTRACT

A semiconductor device has a first substrate and a first electrical component disposed over a first surface of the first substrate. A second electrical component is disposed over a second surface of the first substrate opposite the first surface of the first substrate. The second electrical component exhibits magnetic attraction from magnetic material or a magnetic coil. The first substrate has an opening and the second electrical component has one or more feet extending through the opening in the first substrate. A third electrical component is disposed over a second substrate and the second substrate is disposed over the first substrate. A conductive post connects the first substrate and second substrate. An encapsulant can be deposited around the first electrical component and a shielding layer is disposed over the second electrical component. The second electrical component can provide a power management function.

### FIELD OF THE INVENTION

The present invention relates in general to semiconductor devices and, more particularly, to a semiconductor device and method of forming a power integrated circuit (IC) implemented as a power management integrated circuit (PMIC) with a magnetic core.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor devices, particularly in high frequency applications, such as radio frequency (RF) wireless communications, often contain one or more integrated passive devices (IPDs) to perform necessary electrical functions. Multiple semiconductor die and IPDs can be integrated into a SiP module for higher density in a small space and extended electrical functionality. Within the SIP module, semiconductor die and IPDs are disposed on a substrate for structural support and electrical interconnect. An encapsulant is deposited over the semiconductor die, IPDs, and substrate.

The SIP module includes high speed digital and RF electrical components, highly integrated for small size and low height, and operating at high clock frequencies and high power rating. A heat spreader with thermal interface material is commonly disposed over the SIP module to dissipate excessive heat from various power devices.

### BRIEF DESCRIPTION OF THE DRAWINGS

FIGS. 1a-1c illustrate a semiconductor wafer with a plurality of semiconductor die separated by a saw street;

FIGS. 2a-2w illustrate a process of forming a power IC as a PMIC with a magnetic core;

FIGS. 3a-3h illustrate a process of forming another part of the PMIC;

FIGS. 4a-4b illustrate the PMIC formed as a wafer and singulated into individual packages;

FIGS. 5a-5b illustrate cross-sectional views of the PMIC; and

FIG. 6 illustrates a printed circuit board (PCB) with different types of packages disposed on a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

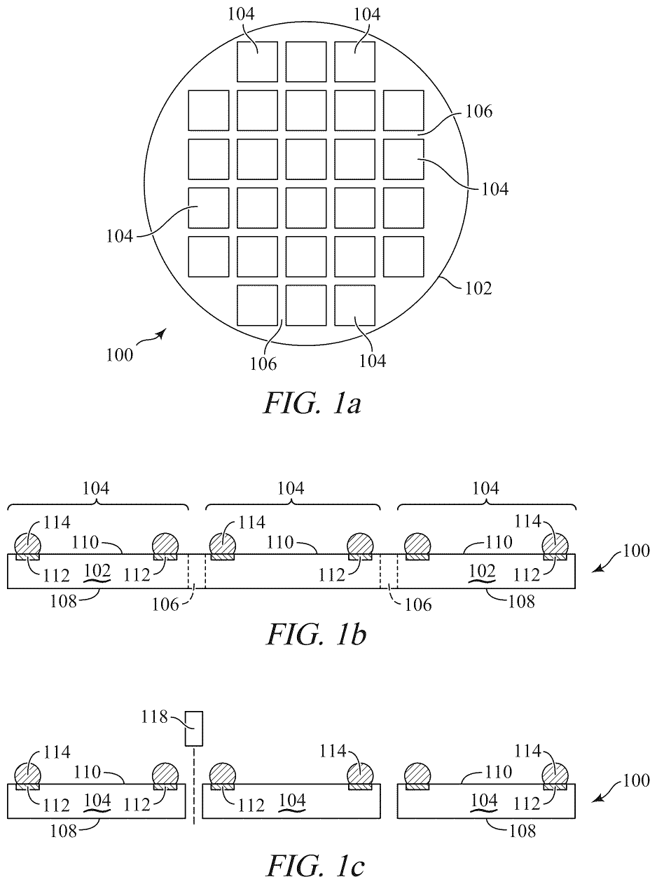

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104 is formed on wafer 100 separated by a non-active, inter-die wafer area or saw street 106. Saw street 106 provides cutting areas to singulate semiconductor wafer 100 into individual semiconductor die 104. Semiconductor wafer 100 can be circular, rectangular, or any other geometric shape. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, or other signal processing circuit. Semiconductor die 104 may also contain IPDs, such as inductors, capacitors, and resistors, for RF signal processing.

An electrically conductive layer 112 is formed over active surface 110 using PVD, CVD, electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

An electrically conductive bump material is deposited over conductive layer 112 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive post 114 using a suitable attachment or bonding process. In one embodiment, the bump material is reflowed by heating the material above its melting point to form balls or bumps 114. In one embodiment, bump 114 is formed over an under bump metallization (UBM) having a wetting layer, barrier layer, and adhesive layer. Bump 114 can also be compression bonded or thermocompression bonded to conductive layer 112. Bump 114 represents one type of interconnect structure that can be formed over conductive layer 112. The interconnect structure can also use bond wires, conductive paste, stud bump, micro bump, or other electrical interconnect. Alternatively, semiconductor wafer 100 is made without bumps 114 and makes electrical connection through conductive layer 112.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die or unit (KGD/KGU) post singulation.

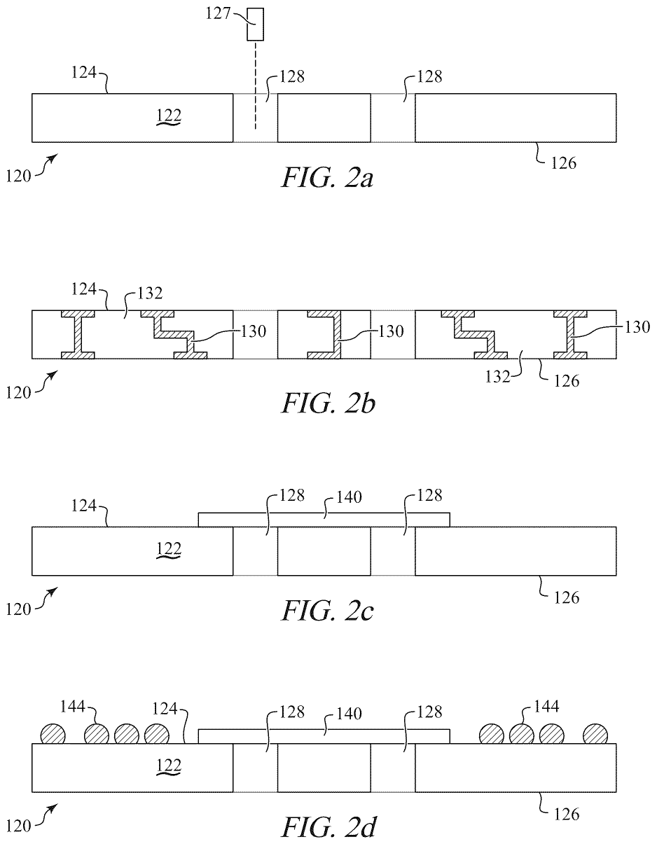

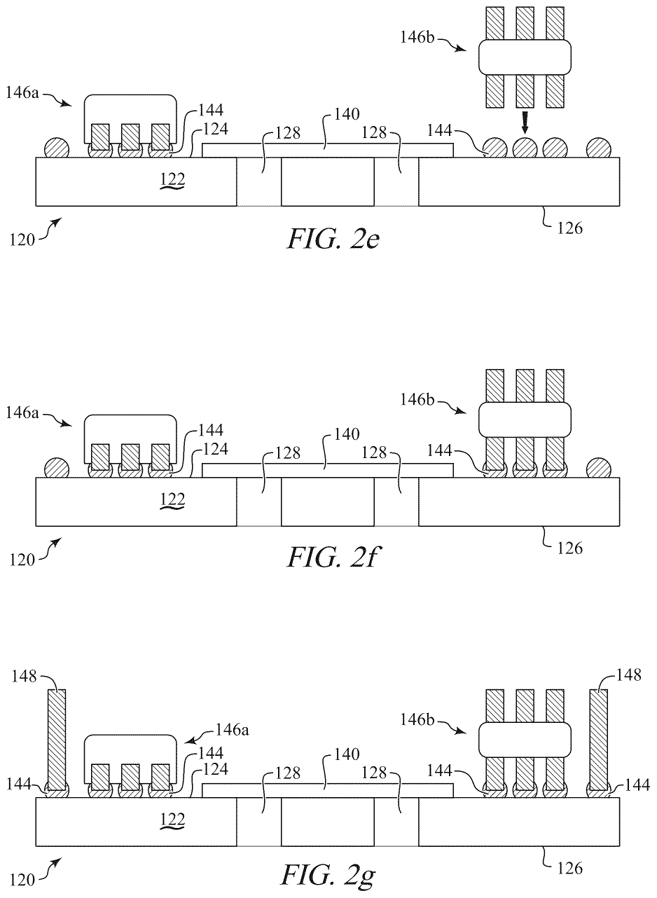

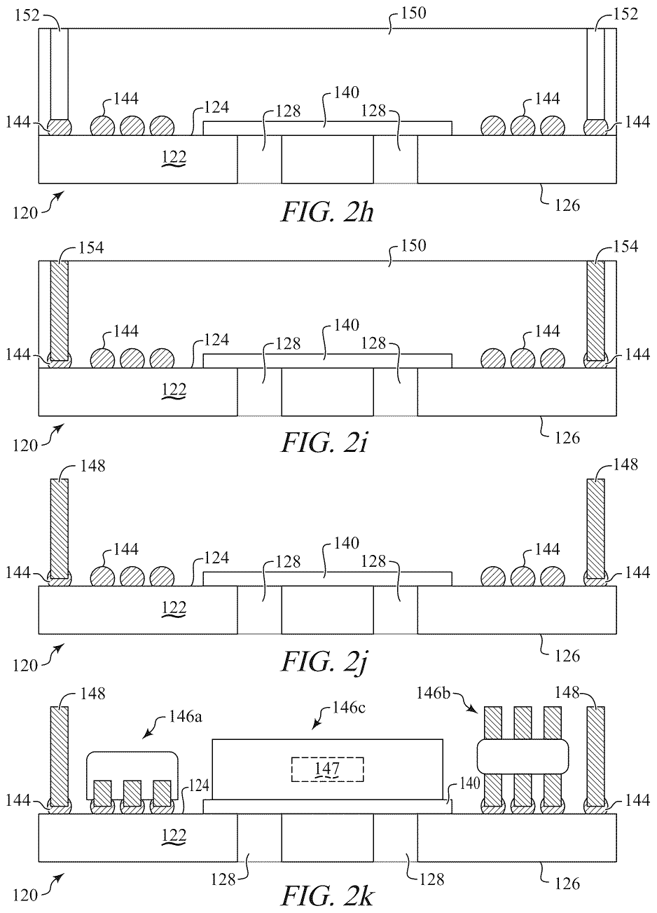

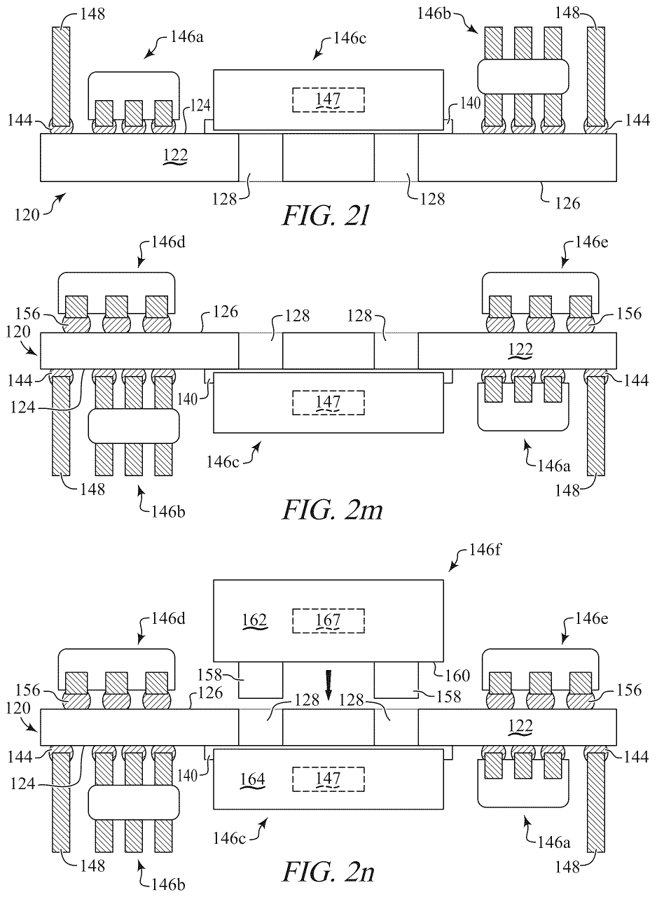

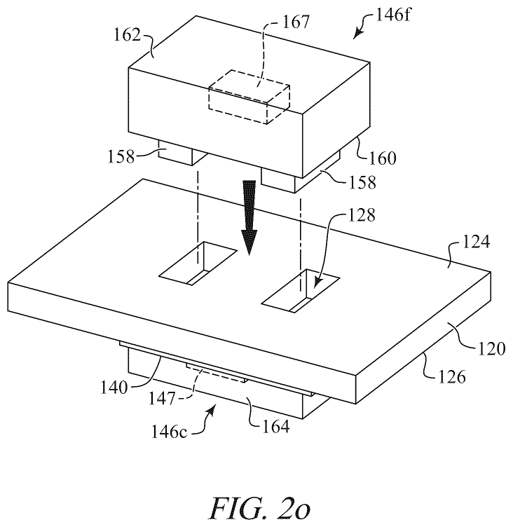

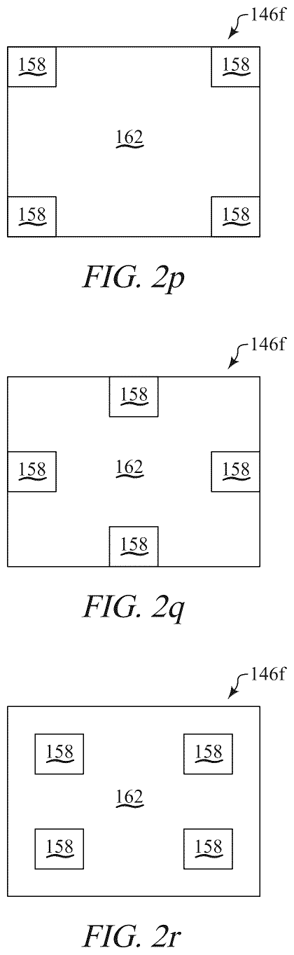

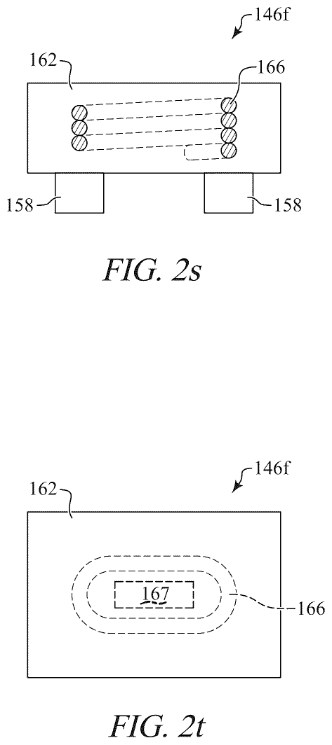

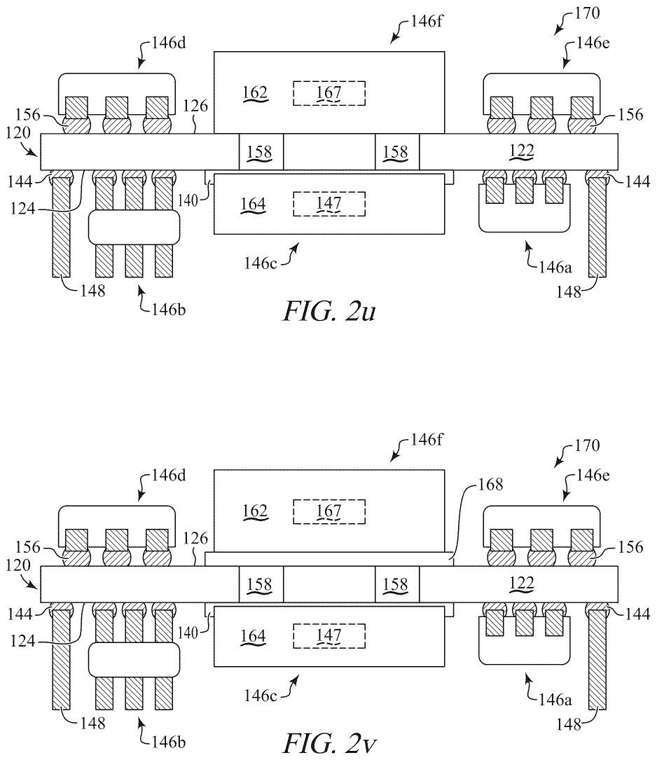

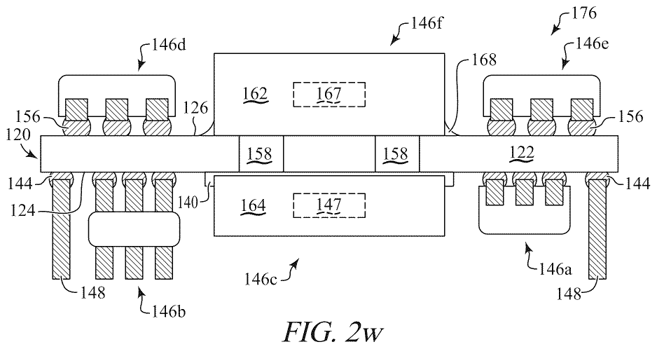

FIGS. 2a-2w illustrate a process of forming a power IC as a PMIC with a magnetic core. FIG. 2a shows a cross-sectional view of a portion of substrate 120 including core material 122, such as silicon, germanium, aluminum phosphide, aluminum arsenide, gallium arsenide, gallium nitride, indium phosphide, silicon carbide, or other bulk material for structural support. Alternatively, core material 122 can be a multi-layer flexible laminate, ceramic, copper clad laminate (CCL), glass, or epoxy molding compound. Core material 122 may contain one or more layers of silicon dioxide (SiO2), silicon nitride (Si3N4), silicon oxynitride (SiON), tantalum pentoxide (Ta2O5), aluminum oxide (Al2O3), solder resist, polyimide, benzocyclobutene (BCB), polybenzoxazoles (PBO), and other material having similar insulating and structural properties. Substrate 120 has a major surface 124 and major surface 126 opposite surface 124. A portion of substrate 120 is removed by an etching process or laser direct ablation (LDA) using laser 127 to form openings 128 extending between surface 124 and surface 126.

In another embodiment, substrate 120 is embodied as an interconnect substrate and can include one or more conductive layers 130 and one or more insulating layers 132, as shown in FIG. 2b. Conductive layers 130 can be one or more layers of Al, Cu, Sn, Ni, Au, Ag, or other suitable electrically conductive material. Conductive layers 130 can be formed using PVD, CVD, electrolytic plating, electroless plating process, or other suitable metal deposition process. Conductive layers 130 provide horizontal electrical interconnect across substrate 120 and vertical electrical interconnect between surface 124 and surface 126 of substrate 120 as a redistribution layer (RDL). Portions of conductive layers 130 can be electrically common or electrically isolated depending on the design and function of semiconductor die 104 and other electrical components. Insulating layers 132 contain one or more layers of SiO₂, Si3N4, SiON, Ta2O5, Al2O3, solder resist, polyimide, BCB, PBO, and other material having similar insulating and structural properties. Insulating layers 132 can be formed using PVD, CVD, printing, lamination, spin coating, spray coating, sintering or thermal oxidation. Insulating layers 132 provide isolation between conductive layers 130. There can be multiple conductive layers like 130 separated by insulating layers 132. In one embodiment, conductive layers 130 and insulating layers 132 are individually formed over surface 124 of substrate 120 as interposer 136. For example, a first conductive layer 130 is formed, followed by a first insulating layer 132. Then a second conductive layer 130 is formed, followed by a second insulating layer 132, and so on to form interconnect substrate 120.

In FIG. 2c, adhesive layer 140 is formed over surface 124 of substrate 120. In one embodiment, adhesive layer 140 can be an epoxy material deposited by printing.

In FIG. 2d, electrically conductive material 144 is formed over surface 124 of substrate 120. In one embodiment, conductive material 144 can be solder paste deposited by printing. Adhesive layer 140 can be formed prior to or after conductive material 144.

In FIG. 2e, a plurality of electrical components 146a-146b is disposed on surface 124 of substrate 120 and electrically and mechanically connected to conductive material 144. Electrical components 146a-146b are each positioned over surface 124 using a pick and place operation. For example, electrical component 146a can be similar to semiconductor die 104 from FIG. 1c with conductive layer 112 or bumps 114 oriented toward surface 124 of substrate 120. Alternatively, electrical component 146a can include other semiconductor die, semiconductor packages, surface mount devices, discrete electrical devices, interconnect structures, or IPDs. In one embodiment, electrical component 146a is a power transistor or other power device capable of conducting high current, and electrical component 146b is an electrical connector or other external interface component.

Electrical components 146a-146b are brought into contact with conductive material 144 and bonded to the conductive material by reflowing bumps 114 and/or the conductive material. FIG. 2f illustrates electrical components 146a-146b electrically and mechanically connected to conductive material 144 on surface 124 of substrate 120.

In FIG. 2g, a plurality of conductive posts or columns or pillars 148 is formed over surface 124 of substrate 120. Conductive posts 148 can be pre-fabricated and then bonded to conductive material 144. In another embodiment, conductive posts 148 can be formed prior to mounting electrical components 146a-146b. For example, photoresist layer 150 is formed over surface 124 of substrate 120, as shown in FIG. 2h. A portion of photoresist layer 150 is removed by an etching process or LDA to form openings 152 in the locations of conductive posts 148. In FIG. 2i, openings 152 are filled with conductive material 154, such as Al, Cu, Sn, Ni, Au, Ag, or other suitable electrically conductive material. In FIG. 2j, photoresist layer 150 is removed leaving conductive posts 148. Electrical components 146a-146b can be added, as in FIGS. 2e-2f, returning to the state of the assembly to FIG. 2g.

In FIG. 2k, electrical component 146c is disposed on adhesive material 140 using a pick and place operation. For example, electrical component 146c can be similar to semiconductor die 104 from FIG. 1c. Alternatively, electrical component 146c can include other semiconductor die, semiconductor packages, surface mount devices, discrete electrical devices, interconnect structures, or IPDs. In one embodiment, electrical component 146c can be a core functional electrical component, such as a microprocessor or PMIC. Electrical component 146c is referred to as the I-core component. Electrical component 146c includes an internal core 147 comprising electrical circuits to execute the electrical functions of the electrical component. For example, electrical component 146c can provide power management capability for electrical components 146a-146b, 146d-146e, and 196a-196d. The power management can include current control, heat dissipation, power factor correction, timing, peak current monitoring, overload, phase control, and other power management functions.

Electrical component 146c is bonded to surface 124 using a vacuum reflow process. Electrical component 146c is placed in a chamber capable of conducting a vacuum or negative pressure. Electrical component 146c is drawn into or pressed into adhesive material 140 by the vacuum, compressing the adhesive material and creating the bond. FIG. 2l illustrates electrical component 146c bonded to adhesive material 140 on surface 124 of substrate 120.

In FIG. 2m, the assembly is inverted and electrically conductive material 156 is formed over surface 126 of substrate 120. In one embodiment, conductive material 156 can be solder paste deposited by printing. A plurality of electrical components 146d-146e is disposed on surface 126 of substrate 120 and electrically and mechanically connected to conductive material 156. Electrical components 146d-146e are each positioned over surface 126 using a pick and place operation. For example, electrical components 146d-146e can be similar to semiconductor die 104 from FIG. 1c with conductive layer 112 or bumps 114 oriented toward surface 126 of substrate 120. Alternatively, electrical components 146d-146e can include other semiconductor die, semiconductor packages, surface mount devices, discrete electrical devices, interconnect structures, or IPDs. In one embodiment, electrical components 146d-146e can be a power transistor or other power device capable of conducting high current. Electrical components 146d-146e are brought into contact with conductive material 156 and bonded to the conductive material by reflowing bumps 114 and/or the conductive material, similar to FIGS. 2e-2f.

In FIG. 2n, electrical component 146f is disposed over surface 126 of substrate 120. Electrical component 146f is positioned over surface 126 using a pick and place operation. Notably, electrical component 146f includes one or more feet or protrusions 158 sized to be compatible with and aligned to openings 128 of substrate 120. Feet 158 are inserted into openings 128 until surface 160 of electrical component 146f is in proximity to or contacts surface 126 of substrate 120. Electrical component 146f is referred to as U-core component by nature of its shape with feet 158.

FIG. 2o shows a perspective view of feet 158 of electrical component 146f being inserted into openings 128 of substrate 120. Feet 158 and portions of body 162 around electrical component 146f are magnetically attractive to the I-core electrical component 146c. For example, feet 158 and portions of body 162 around electrical component 146f can be made with iron, nickel, cobalt, steel, alnico, manganese, ferrite, and flexible rubber, or rare earth elements like samarium, dysprosium, gadolinium, and neodymium. Likewise, portions of body 164 around electrical component 146c are magnetically attractive to feet 158 and portions of body 162 of electrical component 146c. The magnetic material comprising portions of body 162 of electrical component 146c can also be made with iron, nickel, cobalt, steel, alnico, manganese, ferrite, and flexible rubber, or rare earth elements like samarium, dysprosium, gadolinium, and neodymium, albeit with the opposite magnetic pole as feet 158 and portions of body 162 around electrical component 146f. The magnetic attraction can be between electrical component 146f and substrate 120, as the substrate can be made with magnetic material similar to electrical component 146c.

FIGS. 2p-2r show other embodiments for the arrangement of feet 158 with respect to body 162. Feet 158 can be at the corners of body 162, as in FIG. 2p. Feet 158 can be at the sides of body 162, as in FIG. 2q. Feet 158 can be interior to body 162, as in FIG. 2r.

In another embodiment, feet 158 and portions of body 162 of electrical component 146f are made magnetically attractive by routing current through coil 166 disposed around electrical core 167, as shown in FIGS. 2s-2t. The current running through coil 166 creates an electromagnetic field and the core controls the path of electromagnetic field. Core 167 comprises electrical circuits to execute the electrical function of electrical component 146f. For example, electrical component 146f can provide power management capability for electrical components 146a-146b, 146d-146e, and 196a-196d. The power management can include current control, heat dissipation, power factor correction, timing, peak current monitoring, overload, phase control, and other power management functions.

Accordingly, the U-core electrical component 146f is mounted to substrate 120 and the I-core electrical component 146c is mounted to the opposite side of the substrate using pin through hole (PTH). The U-core electrical component 146f is magnetically attractive to the I-core electrical component 146c and/or substrate 120. The magnetic attraction between U-core electrical component 146f and I-core electrical component 146c and/or substrate 120, including feet 158 and portions of body 162, holds electrical component 146f in place, secure to surface 126 of substrate 120. FIG. 2u shows the U-core electrical component 146f with core 167 held in place, secure to surface 126 of substrate 120, by magnetic forces, as assembly 170. Core 167 and core 147 form a closed core with a substantially square shape to reduce losses and increase efficiency. The magnetic field is generated and changed through the coil of the magnetic core, generating current, so it can be operated without a physical connection. Also, the efficiency increases as the core controls the path of electromagnetic field. Core 167 can transmit and receive data with respect to core 147 using a magnetic connection and interface. By connecting substrate 120 through a connector, such as electrical component 146b, high-speed signal transmission and stable electrical signal transmission can be achieved.

In another embodiment, electrical component 146f is disposed over epoxy 168, similar to epoxy 140 with electrical component 146c in FIG. 2k, as shown in FIG. 2v. Electrical component 146f is further held in place with epoxy 168, similar to epoxy 140 with electrical component 146c in FIG. 2l. FIG. 2w shows the U-core electrical component 146f held in place, secure to surface 126 of substrate 120, by magnetic forces and epoxy 168, as assembly 176.

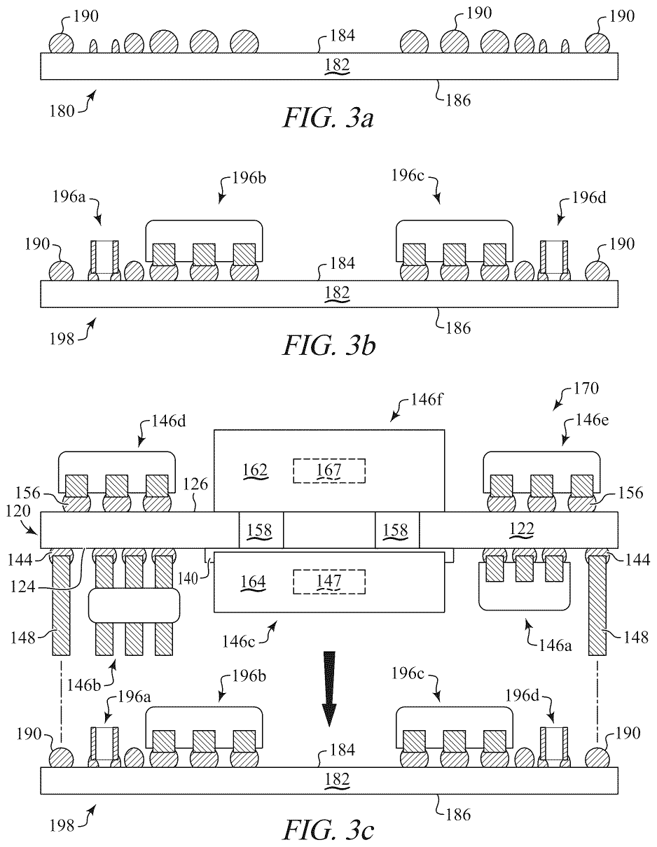

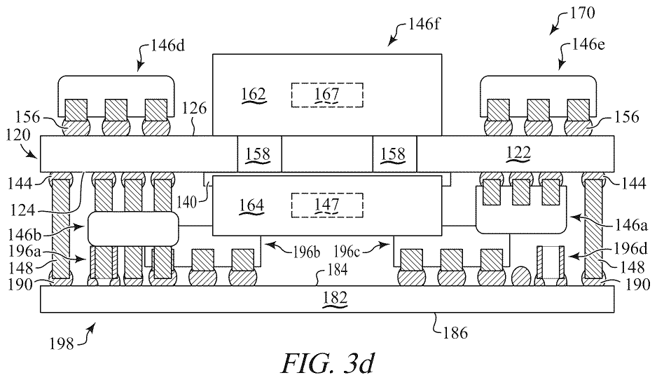

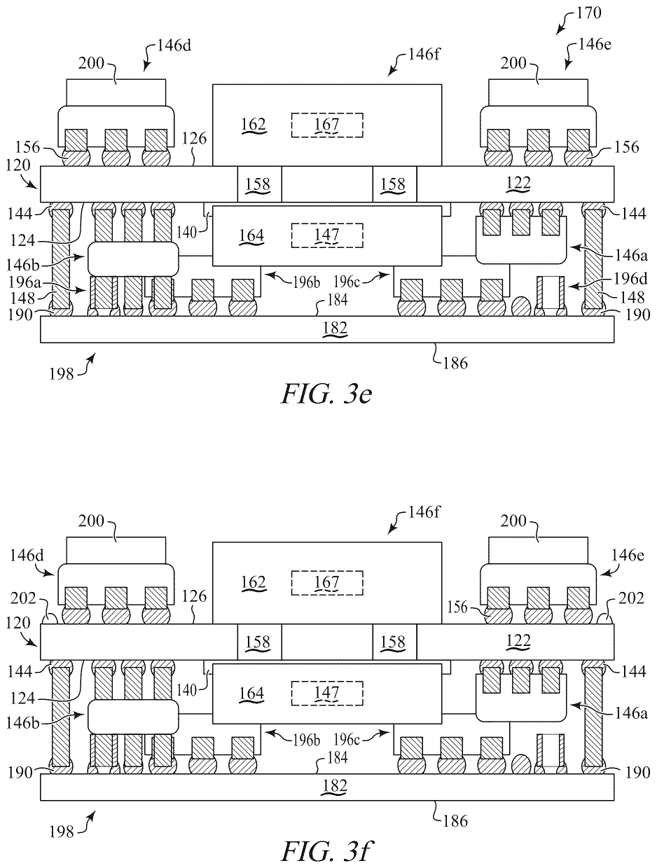

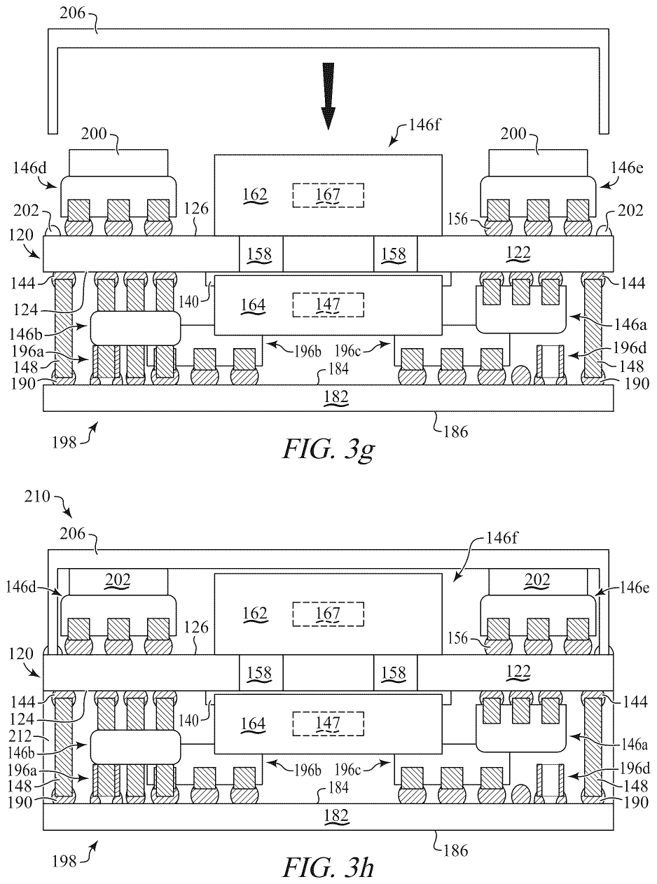

FIG. 3a shows a cross-sectional view of a portion of substrate 180 including core material 182, such as silicon, germanium, aluminum phosphide, aluminum arsenide, gallium arsenide, gallium nitride, indium phosphide, silicon carbide, or other bulk material for structural support. Alternatively, core material 182 can be a multi-layer flexible laminate, ceramic, CCL, glass, or epoxy molding compound. Core material 182 may contain one or more layers of SiO2, Si3N4, SiON, Ta2O5, Al2O3, solder resist, polyimide, BCB, PBO, and other material having similar insulating and structural properties. Substrate 180 has a major surface 184 and major surface 186 opposite surface 184. In another embodiment, substrate 180 can be an interconnect substrate with one or more conductive layers and one or more insulating layers, similar to FIG. 2b. An electrically conductive material 190 is formed over surface 184 of substrate 180. In one embodiment, conductive material 190 can be solder paste deposited by printing.

In FIG. 3b, a plurality of electrical components 196a-196b is disposed on surface 184 of substrate 180 and electrically and mechanically connected to conductive material 190. Electrical components 196a-196d are each positioned over surface 184 using a pick and place operation. For example, electrical components 196a and 196d can be discrete electrical components, such as a transistor, diode, resistor, capacitor, or inductor. Electrical components 196b and 196c can be similar to semiconductor die 104 from FIG. 1c with conductive layer 112 or bumps 114 oriented toward surface 184 of substrate 180. Alternatively, electrical components 196a-196d can include other semiconductor die, semiconductor packages, surface mount devices, discrete electrical devices, interconnect structures, or IPDs. In one embodiment, electrical components 196b-196c are a power transistor or other power device capable of conducting high current.

Electrical components 196a-196d are brought into contact with conductive material 190 and bonded to the conductive material by reflowing bumps 114 and/or the conductive material, similar to FIGS. 2e-2f. FIG. 3b illustrates electrical components 196a-196d electrically and mechanically connected to conductive material 190 on surface 184 of substrate 180 as assembly 198.

In FIG. 3c, assembly 170 from FIG. 2t, or assembly 176 from FIG. 2w, is disposed over assembly 198 with conductive posts aligned with conductive paste 190. Assembly 170 is brought into contact with assembly 198 and conductive posts 148 are bonded to conductive material 190 using vacuum reflow. FIG. 3d illustrates assembly 170 electrically and mechanically connected to assembly 198 and ready for inspection, e.g., automated optical inspection (AOI).

In FIG. 3e, thermal interface material (TIM) 200 is deposited on a back surface of electrical components 146d and 146e. TIM 200 can be made of silicon-based epoxy with thermal conducting fillers containing alumina (Al2O3), Al, Ag, or aluminum zinc oxide. TIM 200 dissipates heat by effectively increasing the contact area between the semiconductor die and heat spreader.

In FIG. 3f, adhesive layer 202 is formed over surface 126 of substrate 120. In one embodiment, adhesive layer 202 can be an epoxy material deposited by printing.

FIG. 3g shows heat spreader or heat sink 206 disposed over electrical components 146d-146f. Heat spreader 206 can be made of one or more layers of Al, Cu, Sn, Ni, Au, Ag, or other suitable thermally conductive material. In one embodiment, heat spreader 206 is Ni-plated Cu. Heat spreader 206 is brought into contact with TIM 200 and adhesive layer 202 and then cured. FIG. 3h shows heat spreader 206 bonded to TIM 200 to provide dissipation of heat from electrical components 146d-146f. TIM 200 exhibits high thermal conductivity and with a large heat sink 206, similar to the PKG body size, the heat generated from transistors such as diodes and MOSFETs is effectively dissipated. The assembly shown in FIG. 3h is referred to as a power IC 210, implemented as a PMIC with a magnetic core. Two cores mounted on the opposite side of the PCB through the PTH mounting method. The two cores form a closed core with a square shape to reduce losses and increase efficiency.

An encapsulant or molding compound 212 is deposited over and around electrical components 146a-146c, as well as assembly 198 and substrates 120 and 180, using a paste printing, compressive molding, transfer molding, liquid encapsulant molding, vacuum lamination, spin coating, or other suitable applicator. Encapsulant 212 can be polymer composite material, such as epoxy resin with filler, epoxy acrylate with filler, or polymer with proper filler. Encapsulant 212 is non-conductive, provides structural support, and environmentally protects the semiconductor device from external elements and contaminants.

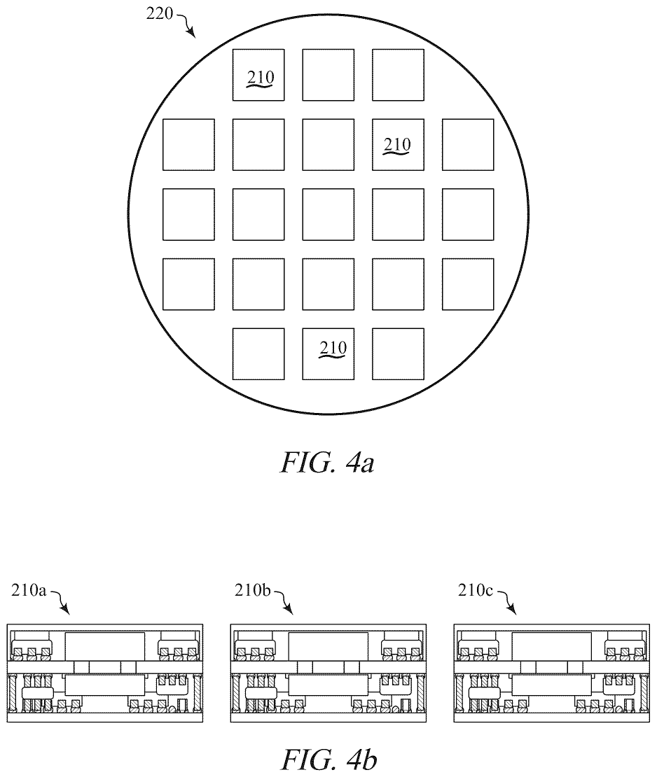

A plurality of power ICs 210 can be formed on wafer 220, as in FIG. 4a. The power ICs 210 are singulated from wafer 220 using a saw blade or laser cutting tool. FIG. 4b shows power IC 210a, 210b, and 210c post singulation.

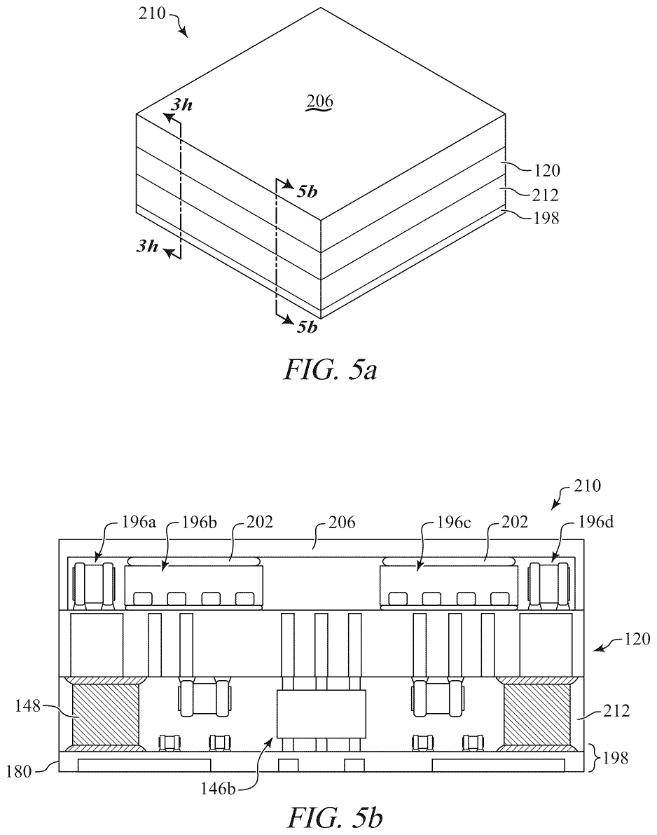

FIG. 5a shows a perspective view of power ICs 210 with assembly 198, substrate 120, and shielding layer 206 covering electrical components 146d-146f. A first cross-sectional view 3h-3h through power ICs 210 would be similar to FIG. 3h in showing electrical components 146c and 146f. A second cross-section view 5b-5b through power ICs 210 could be as shown in FIG. 5b with other electrical components.

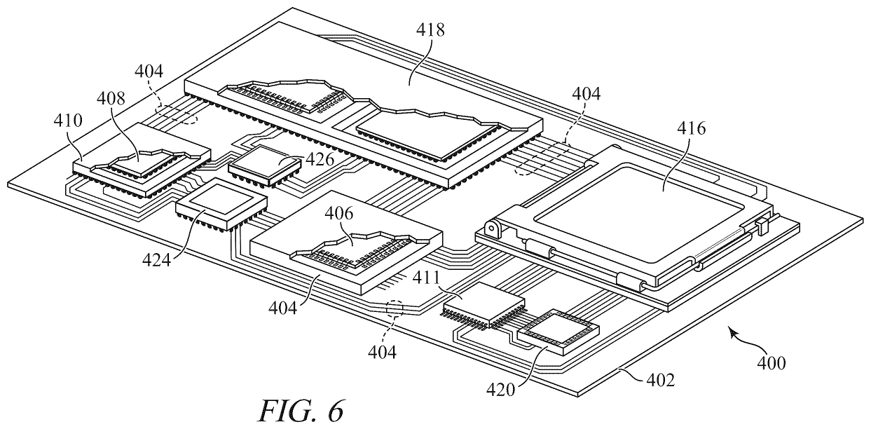

FIG. 6 illustrates electrical device 400 having a chip carrier substrate or PCB 402 with a plurality of semiconductor packages disposed on a surface of PCB 402, including power ICs 210. Electrical device 400 can have one type of semiconductor package, or multiple types of semiconductor packages, depending on the application.

Electrical device 400 can be a stand-alone system that uses the semiconductor packages to perform one or more electrical functions. Alternatively, electrical device 400 can be a subcomponent of a larger system. For example, electrical device 400 can be part of a tablet, cellular phone, digital camera, communication system, or other electrical device. Alternatively, electrical device 400 can be a graphics card, network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 6, PCB 402 provides a general substrate for structural support and electrical interconnect of the semiconductor packages disposed on the PCB. Conductive signal traces 404 are formed over a surface or within layers of PCB 402 using evaporation, electrolytic plating, electroless plating, screen printing, or other suitable metal deposition process. Signal traces 404 provide for electrical communication between each of the semiconductor packages, mounted components, and other external system components. Traces 404 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may have the first level packaging where the die is mechanically and electrically disposed directly on the PCB. For the purpose of illustration, several types of first level packaging, including bond wire package 406 and flipchip 408, are shown on PCB 402. Additionally, several types of second level packaging, including ball grid array (BGA) 410, bump chip carrier (BCC) 412, land grid array (LGA) 416, multi-chip module (MCM) or SIP module 418, quad flat non-leaded package (QFN) 420, quad flat package 422, embedded wafer level ball grid array (eWLB) 424, and wafer level chip scale package (WLCSP) 426 are shown disposed on PCB 402. In one embodiment, eWLB 424 is a fan-out wafer level package (Fo-WLP) and WLCSP 426 is a fan-in wafer level package (Fi-WLP). Depending upon the system requirements, any combination of semiconductor packages, configured with any combination of first and second level packaging styles, as well as other electrical components, can be connected to PCB 402. In some embodiments, electrical device 400 includes a single attached semiconductor package, while other embodiments call for multiple interconnected packages. By combining one or more semiconductor packages over a single substrate, manufacturers can incorporate pre-made components into electrical devices and systems. Because the semiconductor packages include sophisticated functionality, electrical devices can be manufactured using less expensive components and a streamlined manufacturing process. The resulting devices are less likely to fail and are less expensive to manufacture, resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A semiconductor device, comprising:
a first substrate;
a first electrical component disposed over a first surface of the first substrate; and
a second electrical component disposed over a second surface of the first substrate opposite the first surface of the first substrate, wherein the second electrical component exhibits magnetic attraction.

2. The semiconductor device of claim 1, wherein the first substrate includes an opening and the second electrical component includes a foot extending through the opening in the first substrate.

3. The semiconductor device of claim 1, wherein the second electrical component includes magnetic material.

4. The semiconductor device of claim 1, wherein the second electrical component includes a magnetic coil.

5. The semiconductor device of claim 1, further including:
a second substrate; and
a third electrical component disposed over the second substrate and the second substrate being disposed over the first substrate.

6. The semiconductor device of claim 1, wherein the second electrical component provides a power management function.

7. A semiconductor device, comprising:
a first substrate;
a first electrical component disposed over a first surface of the first substrate; and
a second electrical component magnetically attracted to a second surface of the first substrate opposite the first surface of the first substrate.

8. The semiconductor device of claim 7, wherein the first substrate includes an opening and the second electrical component includes a foot extending through the opening in the first substrate.

9. The semiconductor device of claim 7, wherein the second electrical component includes magnetic material.

10. The semiconductor device of claim 7, wherein the second electrical component includes a magnetic coil.

11. The semiconductor device of claim 7, further including:
a second substrate; and
a third electrical component disposed over the second substrate and the second substrate being disposed over the first substrate.

12. The semiconductor device of claim 7, further including a shielding layer disposed over the second electrical component.

13. The semiconductor device of claim 7, wherein the second electrical component provides a power management function.

14. A method of making a semiconductor device, comprising:
providing a first substrate;
disposing a first electrical component over a first surface of the first substrate; and
disposing a second electrical component over a second surface of the first substrate opposite the first surface of the first substrate, wherein the second electrical component exhibits magnetic attraction.

15. The method of claim 14, further including:
providing an opening in the first substrate; and
providing a foot extending from the second electrical component and disposed within the opening in the first substrate.

16. The method of claim 14, wherein the second electrical component includes magnetic material.

17. The method of claim 14, wherein the second electrical component includes a magnetic coil.

18. The method of claim 14, further including:
providing a second substrate;
disposing a third electrical component over the second substrate; and
disposing the second substrate over the first substrate.

19. The method of claim 14, wherein the second electrical component provides a power management function.

20. A method of making a semiconductor device, comprising:
providing a first substrate;
disposing a first electrical component over a first surface of the first substrate; and
disposing a second electrical component magnetically attracted to a second surface of the first substrate opposite the first surface of the first substrate.

21. The method of claim 20, further including:
providing an opening in the first substrate; and
providing a foot extending from the second electrical component and disposed within the opening in the first substrate.

22. The method of claim 20, wherein the second electrical component includes magnetic material.

23. The method of claim 20, wherein the second electrical component includes a magnetic coil.

24. The method of claim 20, further including:
providing a second substrate;
disposing a third electrical component over the second substrate; and
disposing the second substrate over the first substrate.

25. The method of claim 20, wherein the second electrical component provides a power management function.
